(19) United States
(12) Patent Application Publication
(10) Pub. No.: US 2004/0157424 A1
(43) Pub. Date: Aug. 12, 2004

(54) Method of manufacturing electronic device

(75) Inventors: Yoshihiro Kusumi, Tokyo (JP); Takeru Matsuoka, Tokyo (JP); Shoichi Fukui, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., TOKYO (JP)

(21) Appl. No.: 10/603,773

(22) Filed: Jun. 26, 2003

(30) Foreign Application Priority Data
Feb. 12, 2003 (JP) 2003-033307

(51) Int. Cl. H01L 21/44

(52) U.S. Cl. 438/597

(57) ABSTRACT

An AlCu alloy interconnect line (100) including a TiN barrier layer (110), a lower Ti metal layer (120), an AlCu layer (130) and a TiN cap layer (140) is formed on a plasma oxide film formed on a semiconductor substrate in which devices are formed. Heat treatment is conducted to cause Al contained in the AlCu layer (130) and Ti contained in the lower Ti metal layer (120) to react with each other, thereby forming a lower AlTi alloy layer (150) in a lower portion of the AlCu layer (130). A via hole (170) is thereafter formed. A current path extending from the via hole (170) to reach the lower AlTi alloy layer (150) is ensured without passing through the AlCu layer (130), allowing electromigration resistance to be improved.

### BACKGROUND OF THE INVENTION

1. Field of the Invention

The present invention relates to a method of manufacturing an electronic device, and more particularly, to a method of manufacturing an electronic device having a multilayer interconnection structure.

2. Description of the Background Art

With the recent trend toward higher integration of semiconductor devices, the need for a finer multilayer interconnection structure is increasing, and finer Al alloy interconnection with good electromigration resistance is also being required. A conventional multilayer interconnection structure using Al alloys for meeting such demands will be described below.

First, an underlying oxide film is formed on a substrate. Then, a TiN barrier layer of 10 nm thickness, a Ti metal layer of 10 nm thickness, an AlCu layer of 250 nm thickness and a TiN cap layer of 60 nm thickness are formed in this order on the underlying oxide film by sputtering. An AlCu alloy interconnect line is thereby formed.

Next, a resist mask is formed by photolithography, and the AlCu alloy interconnect line is patterned into a predetermined configuration by dry etching.

Then, thermal processing is conducted at 400° C. for about 15 minutes to cause Al contained in the AlCu layer and Ti contained in the Ti metal layer to react with each other, thereby forming a lower AlTi alloy layer in a lower portion of the AlCu layer.

Subsequently, an interlayer dielectric film is formed on the TiN cap layer, i.e., on the AlCu alloy interconnect line.

Next, a via hole is formed in the interlayer dielectric film to such a depth that its bottom surface lies on or in the TiN cap layer. Then, a via hole TiN barrier layer of 70 nm thickness is formed on the inner surface of the via hole by sputtering.

Next, tungsten (W) as a plug material is deposited inside the via hole by CVD (chemical vapor deposition) to fill the via hole.

Subsequently, TiN and W deposited on the interlayer dielectric film are removed by CMP (chemical mechanical polishing) or the like to form a W plug.

The above process is repeated to stack the AlCu alloy interconnect line and interlayer dielectric film alternately in layers, so that an AlCu alloy multilayer interconnection structure is formed. An example of an electronic device having such multilayer interconnection structure is disclosed in Japanese Patent Application Laid-Open No. 2000-114376 (document 1).

A conventional multilayer interconnection structure is such that a problem arises in that an effective film thickness of the AlCu layer is thin, causing electromigration resistance to be reduced. That is, electrons flowing into the AlCu alloy interconnect line from the via hole selectively flow into the AlCu layer of low resistance. Since the AlCu layer has a reduced effective film thickness, electromigration occurs first in the AlCu layer in the vicinity of the via hole. Electrons in turn selectively flow into the TiN cap layer, causing heat generation and resistance increase. This causes the TiN cap layer in the vicinity of the via hole to be melted away, disadvantageously resulting in breaks.

The document 1 discloses a method of manufacturing an electronic device in which a W plug extends through a TiN cap layer to come into contact with an AlCu layer under the TiN cap layer for achieving improved electromigration resistance. However, the method disclosed in the document 1 has a disadvantage in that a wedge-shaped defect occurs in the AlCu layer with temperature rise when forming an interlayer dielectric film, which may result in breaks.

### SUMMARY OF THE INVENTION

It is an object of the present invention to provide a method of manufacturing an electronic device having improved electromigration resistance without any defect in an AlCu layer.

According to a first aspect of the present invention, the method of manufacturing an electronic device includes the following steps (a) through (i). The step (a) is to form a barrier layer containing a Ti atom on an underlying layer. The step (b) is to form a lower Ti metal layer on the barrier layer. The step (c) is to form an AlCu layer on the lower Ti metal layer. The step (d) is to form a cap layer containing a Ti atom on the AlCu layer. The step (e) is to conduct heat treatment on an AlCu alloy interconnect line formed through the steps (a) to (d) to form a lower AlTi alloy layer in a lower portion of the AlCu layer. The step (f) is to form an interlayer dielectric film on the AlCu alloy interconnect line subjected to heat treatment. The step (g) is to form a via hole so as to extend through the interlayer dielectric film and the cap layer to reach the lower AlTi alloy layer in the lower portion of the AlCu layer. The step (h) is to form a via hole barrier layer containing a Ti atom on an inner surface of the via hole. The step (i) is to fill a plug material inside the via hole barrier layer to form a plug.

Defects can be prevented in the AlCu layer when forming the interlayer dielectric film.

According to a second aspect of the invention, the method of manufacturing an electronic device includes the following steps (a) through (i-1). The step (a) is to form a barrier layer containing a Ti atom on an underlying layer. The step (b) is to form a lower Ti metal layer on the barrier layer. The step (c) is to form an AlCu layer on the lower Ti metal layer. The step (d) is to form a cap layer containing a Ti atom on the AlCu layer. The step (e) is to conduct heat treatment on an AlCu alloy interconnect line formed through the steps (a) to (d) to form a lower AlTi alloy layer in a lower portion of the AlCu layer. The step (f) is to form an interlayer dielectric film on the AlCu alloy interconnect line subjected to heat treatment. The step (g-1) is to form a via hole so as to extend through the interlayer dielectric film and the cap layer to reach the AlCu layer. The step (g-2) is to form a via hole Ti metal layer on an inner surface of the via hole. The step (h) is to form a via hole barrier layer containing a Ti atom on an inner surface of the via hole Ti metal layer. The step (i) is to fill a plug material inside the via hole barrier layer to form a plug. The step (i-1) is to conduct heat treatment to form an upper AlTi alloy region in an upper portion of the AlCu layer from the AlCu layer and the via hole Ti metal layer.

In addition to the effect achieved by the first aspect, the resist thickness can be reduced, which improves the accuracy of photolithography.

According to a third aspect of the invention, the method of manufacturing an electronic device includes the following steps (a) through (i). The step (a) is to form a barrier layer containing a Ti atom on an underlying layer. The step (b) is to form a lower Ti metal layer on the barrier layer. The step (c) is to form an AlCu layer on the lower Ti metal layer. The step (c-1) is to form an upper Ti metal layer on the AlCu layer. The step (d-1) is to form a cap layer containing a Ti atom on the upper Ti metal layer. The step (e-1) is to conduct heat treatment on an AlCu alloy interconnect line formed through the steps (a) to (d-1) to form an upper AlTi alloy layer in an upper portion of the AlCu layer and a lower AlTi alloy layer in a lower portion of the AlCu layer. The step (f) is to form an interlayer dielectric film on the AlCu alloy interconnect line subjected to heat treatment. The step (g-3) is to form a via hole so as to extend through the interlayer dielectric film to reach the cap layer. The step (h) is to form a via hole barrier layer containing a Ti atom on an inner surface of the via hole. The step (i) is to fill a plug material inside the via hole barrier layer to form a plug.

In addition to the effect achieved by the first aspect, a depth margin of the via hole with respect to thickness unevenness of the interlayer dielectric film caused by CMP or the like can be increased.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 and 2 illustrate an AlCu alloy interconnect line in an electronic device according to a first preferred embodiment of the present invention;

FIG. 3 illustrates an AlCu alloy interconnect line in an electronic device according to a second preferred embodiment of the invention;

FIG. 4 illustrates an AlCu alloy interconnect line in an electronic device according to a third preferred embodiment of the invention; and

FIGS. 5 and 6 illustrate an AlCu alloy interconnect line in an electronic device according to a fourth preferred embodiment of the invention.

### DESCRIPTION OF THE PREFERRED EMBODIMENTS

First Preferred Embodiment

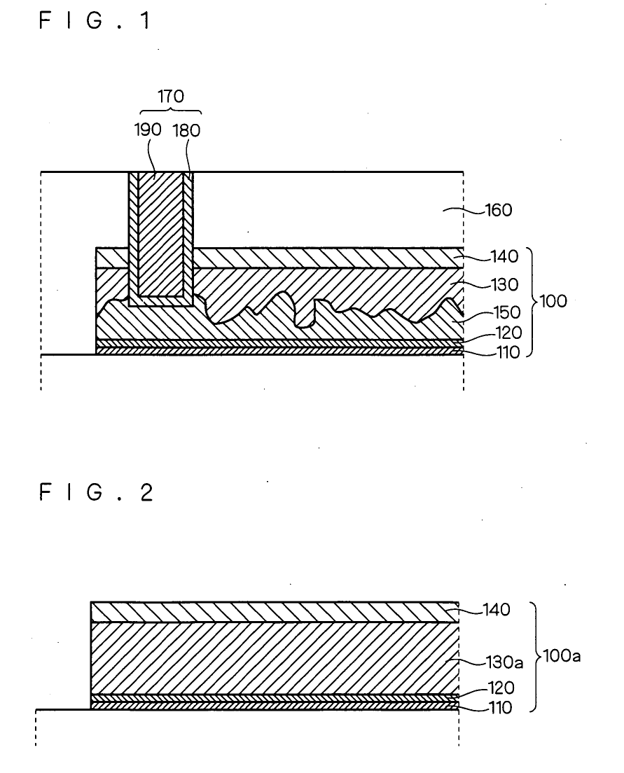

FIG. 1 illustrates an AlCu alloy interconnect line 100 in an electronic device according to a first preferred embodiment of the present invention.

First, as shown in FIG. 2, a TiN barrier layer 110 of about 10 nm thickness, a lower Ti metal layer 120 of about 10 nm thickness, an AlCu layer 130a of about 250 nm thickness and a TiN cap layer 140 of about 60 nm thickness are formed in this order by sputtering on an underlying layer including a semiconductor substrate (not shown) in which, for example, devices are formed and a plasma oxide film (not shown) as a lower dielectric film formed on the semiconductor substrate. An AlCu alloy interconnect line 100a is thereby formed.

Next, a resist mask is formed by photolithography, and the AlCu alloy interconnect line 100a is patterned into a predetermined configuration by dry etching. A KrF resist of about 650 nm thickness may be adopted for the resist mask. For dry etching, anisotropic etching employing a plasma with a gas mixture of Cl₂/BCl₃ may be performed.

Then, heat treatment is conducted by N₂ sintering at about 400° C. for about 15 minutes to cause Al contained in the AlCu layer 130a and Ti contained in the lower Ti metal layer 120 to react with each other, there by forming a lower AlTi alloy layer 150 in a lower portion of the AlCu layer 130a. Although the lower AlTi alloy layer 150 has an uneven top surface as shown in FIG. 1, the film thickness of the lower AlTi alloy layer 150 shall be the distance between an imaginary plane obtained by smoothing the uneven top surface and the bottom surface of the lower AlTi alloy layer 150. Likewise, although the AlCu layer 130 has an uneven bottom surface, the film thickness of the AlCu layer 130 shall be the distance between an imaginary plane obtained by smoothing the uneven bottom surface and the top surface of the AlCu layer 130. The lower AlTi alloy layer 150 is formed in a film thickness of about 50 to 150 nm. The AlCu layer 130 has a reduced film thickness of about 100 to 200 nm as compared to the AlCu layer 130a.

Next, an oxide film is formed on the TiN cap layer 140, i.e., on the AlCu alloy interconnect line 100a by a plasma CVD method employing HDP (high density plasma) or the like. The oxide film is thereafter planarized by CMP to form an interlayer dielectric film 160 of about 750 nm thickness.

Subsequently, a KrF resist (not shown) is coated in a film thickness of about 650 nm on the interlayer dielectric film 160. Photolithography is conducted on the coated KrF resist to form a via hole resist mask (not shown) having a diameter of about φ0.20 μm. Dry etching is thereafter performed to form a via hole 170 in the interlayer dielectric film 160 as shown in FIG. 1. The via hole 170 extends through the TiN cap layer 140 and AlCu layer 130 to reach the lower AlTi alloy layer 150. For dry etching, anisotropic etching employing a plasma with a gas mixture of C₅F₈/O₂/Ar/CO may be performed.

Then, a via hole TiN barrier layer 180 of about 70 nm thickness is formed on the inner surface of the via hole 170 by sputtering.

Next, W as a plug material is deposited inside the via hole 170 by CVD to fill the via hole 170.

Subsequently, TiN and W deposited on the interlayer dielectric film 160 are removed by CMP or the like to form a W plug 190. The AlCu alloy interconnect line 100 is thereby completed.

The above process is repeated to stack the AlCu alloy interconnect line 100 and interlayer dielectric film 160 alternately in layers, so that an AlCu alloy multilayer interconnection structure (not shown) is formed.

During operations, electrons flowing into the AlCu alloy interconnect line 100 from the via hole 170 selectively flow into the AlCu layer 130 having a low resistivity of about 3μΩ/cm², causing electromigration to occur first in the AlCu layer 130 in the vicinity of the via hole 170. However, the structure ensures a current path extending from the via hole 170 to the lower AlTi alloy layer 150 without passing through the AlCu layer 130. Therefore, electrons in turn flow into the lower AlTi alloy layer 150 having a low resistivity of about 30μΩ/cm² next to the AlCu layer 130, which can prevent breaks.

Further, since the lower AlTi alloy layer 150 is formed by heat treatment before forming the interlayer dielectric film 160, a defect does not occur in the AlCu layer 130 when forming the interlayer dielectric film 160. The reason will be described below.

First, the lower AlTi alloy layer 150 is considered to have a lower thermal expansion coefficient than the AlCu layer 130 and lower Ti metal layer 120. Thus, in the case where heat treatment is performed before forming the interlayer dielectric film 160, the AlCu layer 130 and lower Ti metal layer 120 can be prevented from being varied in volume by forming the lower AlTi alloy layer 150. Now, description will be made on the case where the interlayer dielectric film 160 is formed without forming the lower AlTi alloy layer 150 by heat treatment. Temperature rises up to about 400° C. when forming the interlayer dielectric film 160, causing the AlCu alloy interconnect line 100 to be expanded in volume. At this time, variations in volume of the AlCu layer 130 and lower Ti metal layer 120 are to be prevented by forming the lower AlTi alloy layer 150. However, an oxide film is deposited in the state where the lower AlTi alloy layer 150 is not sufficiently formed, which causes the AlCu alloy interconnect line 100 to be fixed with a portion in the vicinity of a side wall thereof partly expanded in volume. Therefore, decrease in temperature in this state will cause shrinkage of the portion in the vicinity of the side wall of the line 100, resulting in a wedge-shaped defect.

Experiments have shown that a defect can be prevented in the AlCu layer 130 when the film thickness of the lower AlTi alloy layer 150 is equal to or greater than about one quarter of that of the AlCu layer 130 as reduced because of formation of the layer 150. It has also been shown that the layer 150 can be formed in the film thickness of equal to or greater than about one quarter of that of the AlCu layer 130 as reduced when heat treatment is performed by N₂ sintering at a temperature ranging from 400 to 450° C. for a time period ranging from 15 to 30 minutes.

As described, the method of manufacturing an electronic device according to the present embodiment ensures a current path extending from the via hole 170 to the lower AlTi alloy layer 150 without passing through the AlCu layer 130, allowing electromigration resistance to be improved. Further, formation of the lower AlTi alloy layer 150 by heat treatment before forming the interlayer dielectric film 160 can prevent a defect in the AlCu layer 130 when forming the film 160.

Electronic devices to which the present invention is applicable include semiconductor devices such as DRAM and SRAM, liquid devices, magnetic heads and the like.

Second Preferred Embodiment

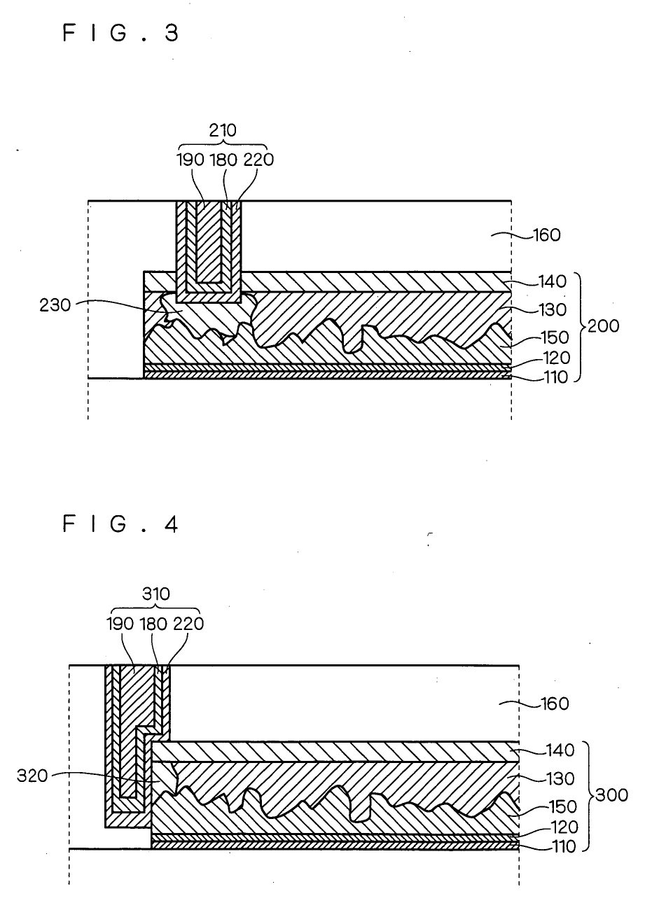

FIG. 3 illustrates an AlCu alloy interconnect line 200 in an electronic device according to a second preferred embodiment of the invention. In FIG. 3, those parts similar to the components of FIG. 1 are identified with the same reference numerals, a repeated explanation of which is thus omitted here.

First, the interlayer dielectric film 160 is formed with the same steps as in the first preferred embodiment.

Next, a KrF resist (not shown) is coated in a film thickness of about 600 nm on the interlayer dielectric film 160. Photolithography is conducted on the coated KrF resist to form a via hole resist mask (not shown) having a diameter of about φ0.20 μm. Dry etching is thereafter performed to form a via hole 210 in the interlayer dielectric film 160. The via hole 210 extends through the TiN cap layer 140 to reach the AlCu layer 130, ending within the layer 130.

Then, a via hole Ti metal layer 220 of about 30 nm thickness and the via hole TiN barrier layer 180 of about 50 nm thickness are formed on the inner surface of the via hole 210 by sputtering.

Next, W as a plug material is deposited inside the via hole 210 by CVD to fill the via hole 210. Here, CVD is performed at about 430° C. Then, Al contained in the upper portion of the AlCu layer 130 and Ti contained in the via hole Ti metal layer 220 react with each other in the vicinity of the bottom surface of the via hole 210. An upper AlTi alloy region 230 is thereby formed. The bottom of the region 230 reaches the lower AlTi alloy layer 150.

Subsequently, TiN and W deposited on the interlayer dielectric film 160 are removed by CMP or the like to form the W plug 190. The AlCu alloy interconnect line 200 is thereby completed.

The above process is repeated to stack the AlCu alloy interconnect line 200 and interlayer dielectric film 160 alternately in layers, so that an AlCu alloy multilayer interconnection structure (not shown) is formed.

As described, with the method according to the present embodiment, the shallowness of the via hole 210 allows the amount of etching to be reduced. Thus, in addition to the effects of the first preferred embodiment, the resist thickness can be reduced, which improves the accuracy of photolithography.

Third Preferred Embodiment

FIG. 4 illustrates an AlCu alloy interconnect line 300 in an electronic device according to a third preferred embodiment of the invention. In FIG. 4, those parts similar to the components of FIGS. 1 and 3 are identified with the same reference numerals, a repeated explanation of which is thus omitted here.

First, the interlayer dielectric film 160 is formed with the same steps as in the first preferred embodiment.

Next, a KrF resist (not shown) is coated in a film thickness of about 565 nm on the interlayer dielectric film 160. Photolithography is conducted on the coated KrF resist to form a via hole resist mask (not shown) having a diameter of about φ0.20 μm. The via hole resist mask is formed in such a position that a via hole 310 to be formed by etching is borderless with respect to the AlCu alloy interconnect line 300. Dry etching is thereafter performed to form the via hole 310 in the interlayer dielectric film 160. The via hole 310 is in contact with a side surface of the AlCu alloy interconnect line 300 and extends to such a depth that its bottom surface is on almost the same level as the bottom surface of the AlCu layer 130.

Then, the via hole Ti metal layer 220 of about 20 nm thickness and via hole TiN barrier layer 180 of about 50 nm thickness are formed on the inner surface of the via hole 310 by sputtering.

Next, W as a plug material is deposited inside the via hole 310 by CVD to fill the via hole 310. Here, CVD is performed at about 430° C. Then, Al contained in a side portion of the AlCu layer 130 and Ti contained in the via hole Ti metal layer 220 react with each other in the vicinity of the side surface of the via hole 310 in contact with the AlCu alloy interconnect line 300. A side AlTi alloy region 320 is thereby formed. The bottom of the region 320 reaches the lower AlTi alloy layer 150.

Subsequently, TiN and W deposited on the interlayer dielectric film 160 are removed by CMP or the like to form the W plug 190. The AlCu alloy interconnect line 300 is thereby completed.

The above process is repeated to stack the AlCu alloy interconnect line 300 and interlayer dielectric film 160 alternately in layers, so that an AlCu alloy multilayer interconnection structure (not shown) is formed.

As described, with the method according to the present embodiment, the via hole 310 is in contact with the side surface of the AlCu alloy interconnect line 300. Thus, in addition to the effects of the first preferred embodiment, the side AlTi alloy region 320 can reach the lower AlTi metal layer 150 without fail even when the via hole Ti metal layer 220 contains less Ti. This allows throughputs to be improved.

Fourth Preferred Embodiment

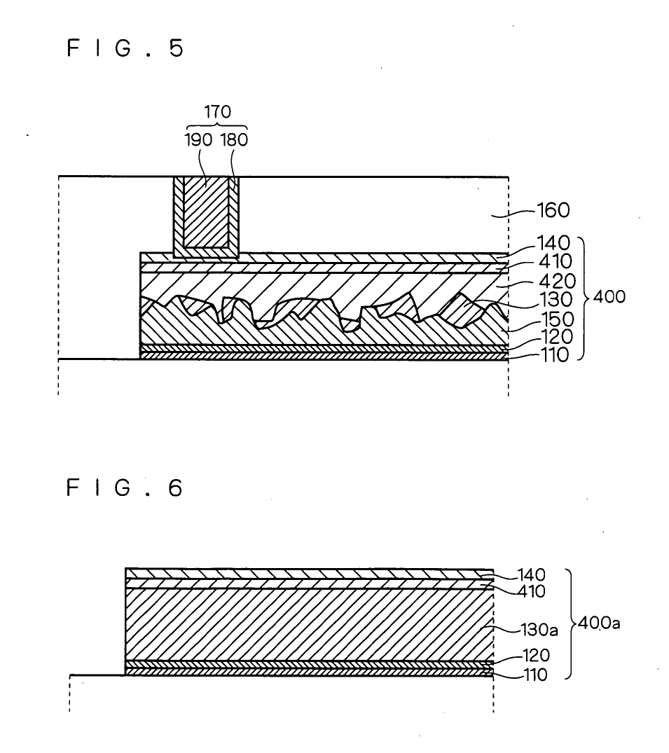

FIG. 5 illustrates an AlCu alloy interconnect line 400 in an electronic device according to a fourth preferred embodiment of the invention. In FIGS. 5 and 6, those parts similar to the components of FIGS. 1 and 2 are identified with the same reference numerals, a repeated explanation of which is thus omitted here.

First, as shown in FIG. 6, the TiN barrier layer 110 of about 10 nm thickness, lower Ti metal layer 120 of about 10 nm thickness, AlCu layer 130a of about 250 nm thickness, an upper Ti metal layer 410 of about 20 nm thickness and the TiN cap layer 140 of about 40 nm thickness are formed in this order by sputtering on an underlying layer including a semiconductor substrate (not shown) in which, for example, devices are formed and a plasma oxide film (not shown) as a lower dielectric film formed on the semiconductor substrate. An AlCu alloy interconnect line 400a is thereby formed.

Next, a resist mask is formed by photolithography, and the AlCu alloy interconnect line 400a is patterned into a predetermined configuration by dry etching. A KrF resist of about 650 nm thickness may be adopted for the resist mask. For dry etching, anisotropic etching employing a plasma with a gas mixture of Cl₂/BCl₃ may be performed.

Then, heat treatment is conducted by N₂ sintering at about 400° C. for about 15 minutes to cause Al contained in the AlCu layer 130a and Ti contained in the lower Ti metal layer 120 to react with each other, thereby forming the lower AlTi alloy layer 150 in the lower portion of the AlCu layer 130a. The lower AlTi alloy layer 150 is formed in a film thickness of about 50 to 150 nm. At the same time, Al contained in the AlCu layer 130a and Ti contained in the upper Ti metal layer 410 also react with each other, thereby forming an upper AlTi alloy layer 420 in an upper portion of the AlCu layer 130a. The layer 420 is formed in a thickness of about 100 to 200 nm. Thus, the layers 150 and 420 are in contact with each other in many positions.

Next, an oxide film is formed on the TiN cap layer 140, i.e., on the AlCu alloy interconnect line 400a by a plasma CVD method employing HDP (high density plasma) or the like. The oxide film is thereafter planarized by CMP to form the interlayer dielectric film 160 of about 750 nm thickness.

Subsequently, a KrF resist (not shown) is coated in a film thickness of about 565 nm on the interlayer dielectric film 160. Photolithography is conducted on the coated KrF resist to form a via hole resist mask (not shown) having a diameter of about φ0.20 μm. Dry etching is thereafter performed to form the via hole 170 as shown in FIG. 5 in the interlayer dielectric film 160. The via hole 170 does not need to extend through the TiN cap layer 140, but may be formed to a such a depth that its bottom surface lies on or within the TiN cap layer 140. For dry etching, anisotropic etching employing a plasma with a gas mixture of C₅F₈/O₂/Ar/CO may be performed.

Then, the via hole TiN barrier layer 180 of about 70 nm thickness is formed on the inner surface of the via hole 170 by sputtering.

Next, W as a plug material is deposited inside the via hole 170 by CVD to fill the via hole 170.

Subsequently, TiN and W deposited on the interlayer dielectric film 160 are removed by CMP or the like to form a W plug 190. The AlCu alloy interconnect line 400 is thereby completed.

The above process is repeated to stack the AlCu alloy interconnect line 400 and interlayer dielectric film 160 alternately in layers, so that an AlCu alloy multilayer interconnection structure (not shown) is formed.

As described, with the method according to the present embodiment, it is sufficient that the via hole 170 be formed to a such a depth that its bottom surface lies on or within the TiN cap layer 140 without the need to extend through the layer 140. This makes it unnecessary to increase the amount of etching even when the interlayer dielectric film 160 has a great thickness. Therefore, in addition to the effects of the first preferred embodiment, a depth margin of the via hole 170 with respect to the thickness unevenness of the film 160 caused by CMP or the like can be increased.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing an electronic device, comprising the steps of:
(a) forming a barrier layer containing a Ti atom on an underlying layer;
(b) forming a lower Ti metal layer on said barrier layer;
(c) forming an AlCu layer on said lower Ti metal layer;
(d) forming a cap layer containing a Ti atom on said AlCu layer;
(e) conducting heat treatment on an AlCu alloy interconnect line formed through said steps (a) to (d) to form a lower AlTi alloy layer in a lower portion of said AlCu layer;
(f) forming an interlayer dielectric film on said AlCu alloy interconnect line subjected to heat treatment;
(g) forming a via hole so as to extend through said interlayer dielectric film and said cap layer to reach said lower AlTi alloy layer in said lower portion of said AlCu layer;
(h) forming a via hole barrier layer containing a Ti atom on an inner surface of said via hole; and
(i) filling a plug material inside said via hole barrier layer to form a plug.

2. A method of manufacturing an electronic device, comprising the steps of:
(a) forming a barrier layer containing a Ti atom on an underlying layer;
(b) forming a lower Ti metal layer on said barrier layer;
(c) forming an AlCu layer on said lower Ti metal layer;
(d) forming a cap layer containing a Ti atom on said AlCu layer;
(e) conducting heat treatment on an AlCu alloy interconnect line formed through said steps (a) to (d) to form a lower AlTi alloy layer in a lower portion of said AlCu layer;
(f) forming an interlayer dielectric film on said AlCu alloy interconnect line subjected to heat treatment;
(g-1) forming a via hole so as to extend through said interlayer dielectric film and said cap layer to reach said AlCu layer;
(g-2) forming a via hole Ti metal layer on an inner surface of said via hole;
(h) forming a via hole barrier layer containing a Ti atom on an inner surface of said via hole Ti metal layer;
(i) filling a plug material inside said via hole barrier layer to form a plug; and
(i-1) conducting heat treatment to form an upper AlTi alloy region in an upper portion of said AlCu layer from said AlCu layer and said via hole Ti metal layer.

3. A method of manufacturing an electronic device, comprising the steps of:
(a) forming a barrier layer containing a Ti atom on an underlying layer;
(b) forming a lower Ti metal layer on said barrier layer;
(c) forming an AlCu layer on said lower Ti metal layer;
(c-1) forming an upper Ti metal layer on said AlCu layer;
(d-1) forming a cap layer containing a Ti atom on said upper Ti metal layer;
(e-1) conducting heat treatment on an AlCu alloy interconnect line formed through said steps (a) to (d-1) to form an upper AlTi alloy layer in an upper portion of said AlCu layer and a lower AlTi alloy layer in a lower portion of said AlCu layer;
(f) forming an interlayer dielectric film on said AlCu alloy interconnect line subjected to heat treatment;
(g-3) forming a via hole so as to extend through said interlayer dielectric film to reach said cap layer;
(h) forming a via hole barrier layer containing a Ti atom on an inner surface of said via hole; and
(i) filling a plug material inside said via hole barrier layer to form a plug.

4. The method according to claim 2, wherein
said steps (i) and (i-1) are performed in the same step.

5. The method according to claim 1, wherein
said step (e) includes the step of conducting heat treatment on said AlCu layer and said cap layer in an N₂ atmosphere at a temperature between 400 and 450° C. for a time period between 15 and 30 minutes.

6. The method according to claim 2, wherein
said step (e) includes the step of conducting heat treatment on said AlCu layer and said cap layer in an N₂ atmosphere at a temperature between 400 and 450° C. for a time period between 15 and 30 minutes.

7. The method according to claim 3, wherein
said step (e-1) includes the step of conducting heat treatment on said AlCu layer and said cap layer in an N₂ atmosphere at a temperature between 400 and 450° C. for a time period between 15 and 30 minutes.

8. The method according to claim 1, wherein
said lower AlTi alloy layer has a thickness equal to or greater than one quarter of a thickness of said AlCu layer.

9. The method according to claim 2, wherein
said lower AlTi alloy layer has a thickness equal to or greater than one quarter of a thickness of said AlCu layer.

10. The method according to claim 3, wherein
said lower AlTi alloy layer has a thickness equal to or greater than one quarter of a thickness of said AlCu layer.
